(19) United States
(12) Patent Application Publication
(10) Pub. No.: US 2012/0099274 A1
(43) Pub. Date: Apr. 26, 2012

(54) DEVICES AND METHODS PROVIDING FOR INTRA-DIE COOLING STRUCTURE RESERVOIRS

(75) Inventor: Bradley J. Winter, Edina, MN (US)

(73) Assignee: COOLSILICON LLC, Edina, MN (US)

(21) Appl. No.: 13/382,838

(22) PCT Filed: Jul. 9, 2010
(86) PCT No.: PCT/US2010/041577

§ 371 Date: Jan. 6, 2012

Related U.S. Application Data
(60) Provisional application No. 61/224,735, filed on Jul. 10, 2009.

(51) Int. Cl. H01L 23/34; F28F 9/007

(52) U.S. Cl. 361/689; 165/67

(57) ABSTRACT

Devices, systems, and methods for semiconductor die temperature management are described and discussed herein. An IC device is described that includes at least one intra-die cooling structure. In an embodiment, the IC device includes at least one coolant reservoir and at least one coolant channel disposed wholly within integral layers of the semiconductor die. The at least one coolant reservoir includes at least one through-reservoir via. The at least one through-reservoir via may be constructed to provide structural support to the at least one coolant reservoir. The at least one through-reservoir via may also be constructed to provide a path for the transfer of thermal energy, electrical signals, and/or power signals. The at least one through-reservoir via may be constructed to provide any combination of structural support and thermal energy transfer, electrical signal transfer, or power transfer.

### FIELD OF THE INVENTION

The invention relates generally to integrated circuits and, more particularly, to temperature management of integrated circuits.

### BACKGROUND OF THE INVENTION

Designers of Integrated Circuit (IC) technology typically strive to provide IC devices that take up a minimum amount of space, and operate reliably at high speeds while consuming a minimum of power. Of increasing importance in IC design is the management of heat generated by device structures of an IC, namely transistors.

The amount of heat generated in a particular IC, or portion of an IC, is dependent at least in part on a number of transistors, the frequency (speed) at which they operate, and/or an amount of electrical energy consumed. This generated heat may cause a variety of operational and/or structural issues. A “hot” IC may operate at limited speed. Many authors have posited that for every 10 degrees in heat reduction, a typical IC will operate at a 2% higher operating frequency. In addition, a “hot” IC may suffer from data and other reliability issues, and may consume more power than a device operating at lower temperatures. The IC may even fail functionally or physically.

Recently, ever-increasing consumer demand for improved IC performance has caused IC designers to look to multi-substrate IC devices in which a plurality of integral IC device layers (substrate layers in which transistors or other IC device structures are formed) are stacked and interconnected in a single die. By utilizing multi-substrate designs, an IC can be provided in a more compact arrangement and lengths of wire routes (electrical connections between IC devices structures such as transistors) can be reduced. Shorter wire lengths may improve operation speeds, reduce parasitic effects on circuit operation, and improve a designer's ability to meet timing requirements.

Because multi-substrate IC devices incorporate transistors arranged in proximity in both horizontal and vertical dimensions, they may be more susceptible to the effects of heat. As such, it may be difficult to remove heat from such devices by traditional methods.

Some single or multi-substrate ICs are formed with silicon-on-insulator (SOI) structures that include an insulating layer formed between different semiconductor substrate layers and/or IC die. These insulating layers may trap heat in the IC, which may exacerbate issues related to the presence of heat.

Many technologies have been developed to remove heat from an IC, such as, for example, heat sinks One example of a heat sink is described in U.S. Pat. No. 4,807,018 to Cellai, which describes a metallic structure adapted to be thermally coupled with one or more exterior surfaces of an IC die or package to transfer heat from the IC into the surrounding environment. Heat sinks may be coupled to an IC on a PC board, or may be included within an IC package.

Other solutions to IC heat management utilize fluid to cool an IC. For example, U.S. Pat. No. 5,388,635 to Gruber et al., U.S. Pat. No. 4,894,709 to Phillips et al., U.S. Pat. No. 7,219,713 to Gelorme et al., U.S. Pat. No. 7,157,793 to Torkington, et al., and U. S. Pat. No. 5,210,440 to Long each describe devices adapted to be placed in contact with or in proximity to one or more surfaces of an IC to circulate fluid in order to cool the IC. Additional approaches, such as described in U.S. Pat. No. 7,170,164 to Chen et al, describe the formation of trenches in a surface of an IC, and the circulation of fluid through the trenches to cool the device. Still other approaches describe the formation of micro-fluidic channels at a back surface of a semiconductor die to dissipate heat. Similarly, other approaches provide for the formation of micro-channels on a surface of a plurality of stacked and interconnected die, such as described in A Cool Innovation Stacks Microprocessors, Tom Adams (Chip Scale Review, pp. 24-29, January 2009, http://e-ditionsbyfry.com/Olive/AM3/CSR/Default.htm?href=CSR/2009/01/01).

Other solutions have also been proposed. For example, U.S. Pat. No. 6,389,582 to Valainis et al. describes a thermal driven placement system for the automated placement of components of an IC design based on a thermal model of the design. Similarly, U.S. Pat. Pub. No. 2009/0024969 to Chandra describes the creation of a thermal model of an IC design and modifying one or more thermal management systems based on the thermal model. A thermal model of an IC design may include designations of “hot spots”, i.e., those portions of the IC that generate a relatively greater amount of heat than other regions or portions of the IC.

Still other approaches provide one or more metallic heat flow paths internal to an IC die itself to remove heat from the design. For example, U.S. Pat. No. 5,955,781 to Joshi et al. describes the formation of heat conductive metallic structures internal to an IC design to dissipate heat directly from hotter elements of the IC. Other approaches, such as described in U.S. Pat. Pub. 2008/0266787 to Gosset et al., describe the formation of micro-fluidic channels in metallization layers of a single substrate IC die. The channels are coupled to an extra-die fluidic cooling circulation driver.

While the above-mentioned approaches for IC temperature management may mitigate the effects of heat on IC device operation, there is a need for improvements in IC thermal management.

### SUMMARY

The techniques of this disclosure are directed to improvements in IC device temperature management. According to these techniques, an IC device may include one or more through-reservoir vias (TRV). The one or more TRV may include at least one portion disposed in a coolant reservoir of the IC die. The one or more TRV may provide structural support for the coolant reservoir. In addition, the one or more TRV may be configured to transfer energy from within the IC device external to the IC device. For example, the one or more TRV may be configured to transfer one or more of thermal, electrical signal, or power energy from within the IC device external to the IC device.

In one example, an integrated circuit (IC) device is described herein. The IC device includes a plurality of integral layers. The IC device further includes at least one coolant reservoir integral to at least one of the plurality of integral layers and configured to house a fluid for the thermal management of the IC device. The IC device further includes at least one through reservoir via (TRV) configured to provide structural support for the at least one coolant reservoir. The at least one TRV is further configured to provide a path for the transfer of energy between the IC device and one or more additional structures external to the IC device.

In another example, a method is described herein. The method includes transferring energy between an IC device and at least one structure external to the IC device. The IC device includes a plurality of integral layers and a coolant reservoir integral to at least one of the plurality of integral layers. The coolant reservoir is configured to house a fluid for the thermal management of the IC device. Transferring the energy comprises transferring the energy through at least one through reservoir via (TRV) configured to provide structural support for the at least one coolant reservoir.

In another example, an integrated circuit (IC) device is described herein. The IC device includes a plurality of layers. The IC device further includes means for housing a fluid for the thermal management of the IC device integral to at least one of the plurality of integral layers. The IC device further includes means for providing structural support for the means for housing the fluid, wherein the means for providing structural support are further for providing a path for the transfer of energy between the IC device and one or more additional structures external to the IC device.

### BRIEF DESCRIPTION OF THE DRAWINGS

The invention may be more completely understood in consideration of the following detailed description of various embodiments of the invention in connection with the accompanying drawings, in which:

FIG. 1 illustrates generally an IC die including an intra-die cooling structure that includes a coolant reservoir according to one embodiment.

FIG. 2 illustrates generally an IC die including an intra-die cooling structure that includes a coolant reservoir according to another embodiment.

FIG. 3 illustrates generally a block diagram of an IC die that includes a multi-function through-reservoir via according to one embodiment.

FIG. 4 illustrates generally an IC die that includes a plurality of through-reservoir vias according to one embodiment.

FIGS. 5A-G illustrate generally a method of forming a reservoir layer of an IC die that includes a plurality of through-reservoir vias according to one embodiment.

FIG. 6 illustrates generally a reservoir layer of an IC die that includes a plurality of through-reservoir vias according to one embodiment.

FIG. 7 illustrates generally a reservoir layer of an IC die that includes a plurality of through-reservoir vias according to another embodiment.

FIG. 8 illustrates generally a reservoir layer of an IC die that includes a plurality of cooling plugs according to one embodiment.

FIG. 9 illustrates generally a reservoir layer of an IC die that includes a plurality of cooling plugs according to another embodiment.

FIG. 10 illustrates generally a reservoir layer of an IC die that includes a plurality of through-reservoir vias and a thermal slug according to another embodiment.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION OF THE PREFERRED EMBODIMENTS

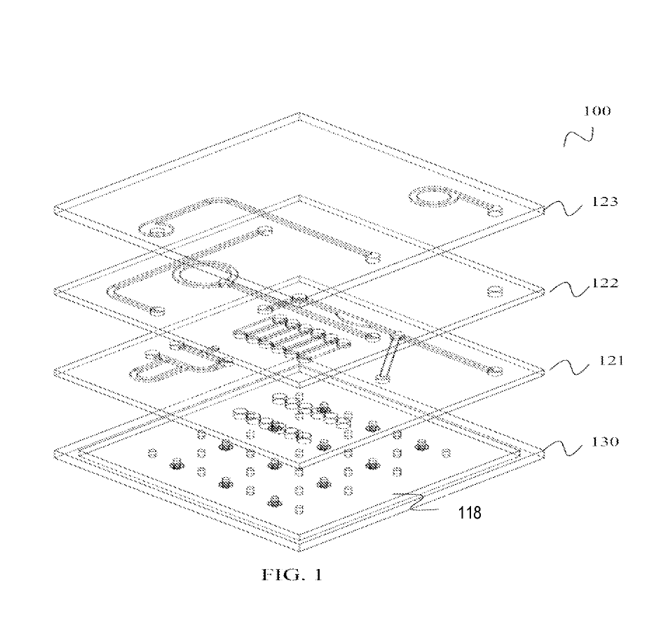

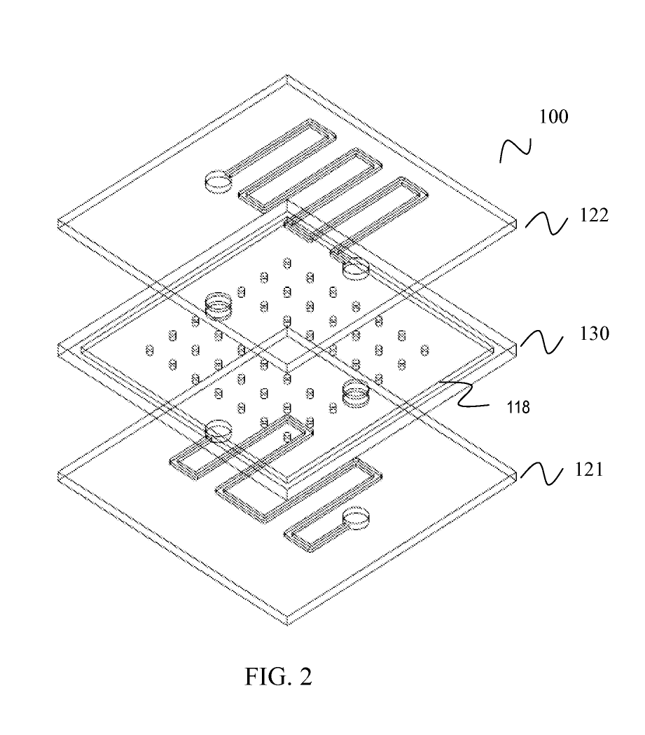

FIG. 1 illustrates generally one embodiment of an IC die 100 that includes an intra-die cooling structure according to various aspects of the invention described herein. As shown in FIG. 1, the intra-die cooling structure includes various intra and inter-layer cooling channels defined in integral layers 121-123 of semiconductor die 100. Layers of die 100 as described herein may be considered integral in the sense that they are adjacent layers of a single die 100. In various embodiments, layers 121-123 of die 100 may be any combination of device layers, metallization/via, routing, or power layers, or any other layers that may be part of an IC device comprising IC die 100. The channels may be fluidically coupled to a reservoir 118 defined in integral layer 130. Layer 130 may be formed integral to one or more other layers of die 100, e.g., layer 121 in the example of FIG. 1. In other embodiments, as shown in FIG. 2, reservoir 118 may be defined in between other integral layers 122, 121 of die 100 (only two die layers in addition to reservoir are shown in the FIG. 2 example). In other embodiments not depicted, die 100 may include multiple reservoirs 118, for example at topmost and bottom most layers of die 100. Various aspects of intra-die cooling structures are described in U.S. patent application Ser. Nos. 12/480,650, 12/480,652, and 12/480,654 to the instant inventor, all of which are incorporated by reference herein in their entirety.

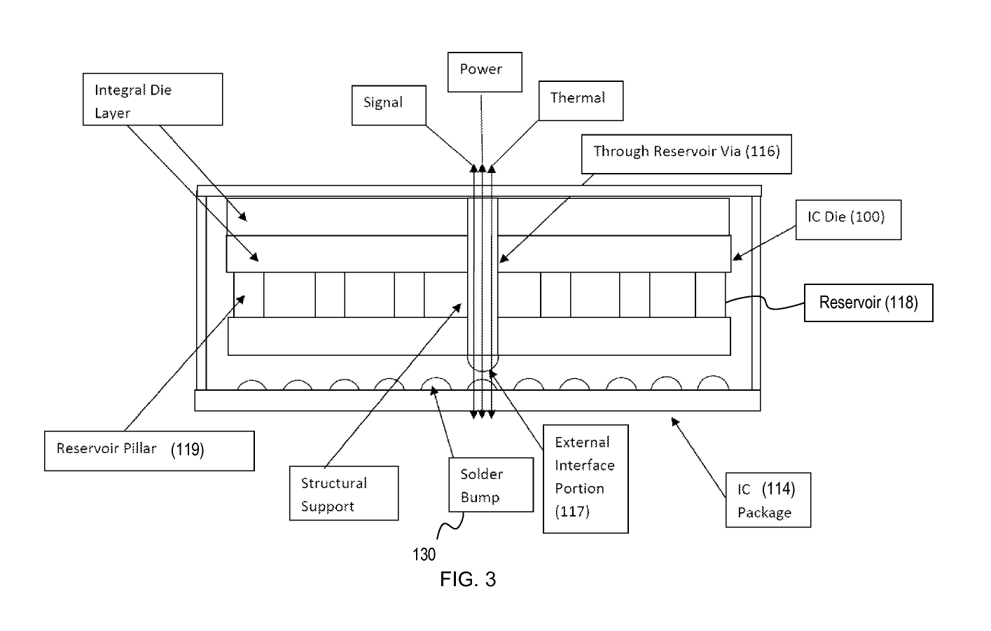

As depicted in the block diagram of FIG. 3, an intra-die coolant reservoir 118 may include at least one through-reservoir via (TRV) 116, which may be adapted to serve a plurality of different functions. TRV 116 may provide structural support for reservoir 118 such that reservoir 118 is suitable to house a coolant fluid. TRV 116 may also or instead be configured as a path for the transfer of energy from within die 100 to one or more structures external to die 100. For example, TRV 116 may be configured as a path for the transfer of thermal, electrical signal, and/or electrical power energy from to external to die 100. In some examples, TRV 116 may be formed of one or more electrically or thermally conductive materials, for example a metal such as gold, aluminum, or copper.

In an embodiment, the coolant fluid is comprised of a liquid and a gas. In an embodiment, the inclusion of a gas enables liquid to expand due to heat without affecting structural integrity of the die. In another embodiment, the liquid is a two-phase liquid adapted to at least partially evaporate at a particular temperature. In one embodiment, the two-phase liquid is adapted to partially evaporate at or near an operating temperature of an IC, such that should a temperature of an IC become too high, a gas is present to prevent pressure of the liquid from causing damage to IC structural integrity. The coolant fluid may be one or more combinations of liquid and/or gas, for example any combination of: water (e.g. de-ionized water), aqueous copper II sulfate, gallium (liquid metal), various concentrations of saline (or other salt derivative) solutions, organic liquids (including those with a low evaporation temperature that form a two phase mixture), emulsions, solids floating in liquids, inert gasses, air, or any liquid or gas now known or later developed.

Through-reservoir via (TRV) 116 may further be configured to provide a path for the transfer of energy between die 100 and one or more additional structures external to die 100. For example, TRV 116 may provide a path for the transfer of thermal, electrical signal, and/or electrical power energy between die 100 and one or more additional structures external to die 100. In some embodiments, TRV 116 may provide a path for the transfer of energy from one or more integral layers of die 100. In other examples, TRV 116 may provide a path for the transfer of energy from reservoir 118. For purposes of energy transfer, TRV 116 may be formed of one or more electrically and/or thermally conductive materials. For example, TRV 116 may be formed of a metallic material such as copper, gold, or aluminum for electrical and/or thermal energy transfer.

TRV 116 may also include one or more external interface portions 117. External interface portion 117 may take the form of a solder bump thermally and/or electrically coupled to TRV 116. In one embodiment, the solder bump may be formed of a conductive material, such as a metal. In some embodiments, external interface portion 117 may be adapted to interface with corresponding bumps external to die 100. In other embodiments not depicted in FIG. 3, TRV 116 may be constructed to provide at a surface of IC die 100 at least one electrical contact (e.g., a solder pad), enabling electrical coupling by use of a an electrically conductive paste or cream, soldering, or other form of electrical coupling. In an embodiment, external interface portions 117 of a plurality of through-reservoir vias 116 may be constructed and arranged to interface with one or more flip-chip or ball grip arrays of bump connections according to any of a variety of industry standard arrangements or other arrangements. In the embodiment depicted in FIG. 3, through-reservoir via 116 and interface portions 117 on a bottom external surface of die 100 are constructed to interface with one or more bump connections 115 in an IC package 114 or PC board onto or into which die 100 is placed or mounted. In other embodiments, interface portions 117 may be presented at a top portion (in relation to the example of FIG. 3) of die 100 to enable signal, power, or thermal coupling to one or more structures located at or coupled to a top portion of an IC package 114.

In some embodiments, external interface portion 117 may be thermally coupleable to one or more heat dissipation structures (e.g., via one or more solder bumps 115), such as a heat sink, thermal slug (for example on a PC board or within an IC package) or extra-die micro-fluidic channel(s), for the dissipation of heat external to die 100. In other examples, external interface portion 117 may be electrically coupleable to one or more circuits or other electrical connections (e.g., wire bond, trace) for the transfer of electrical signal or power signal energy.

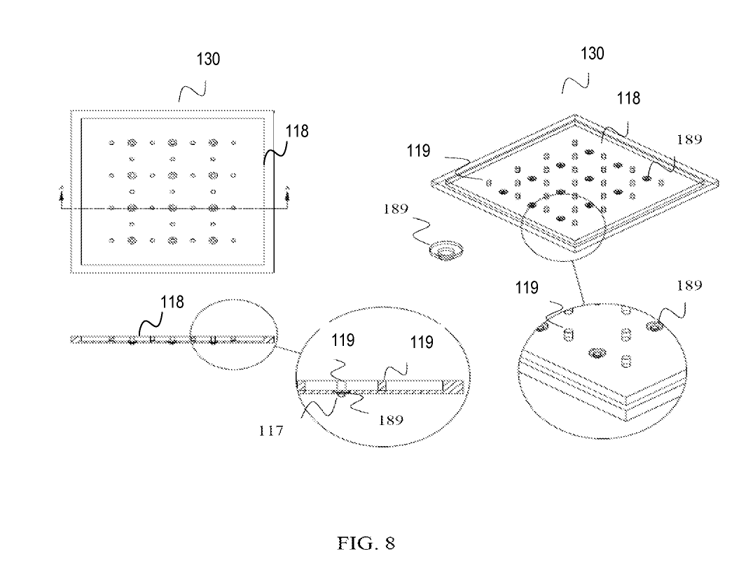

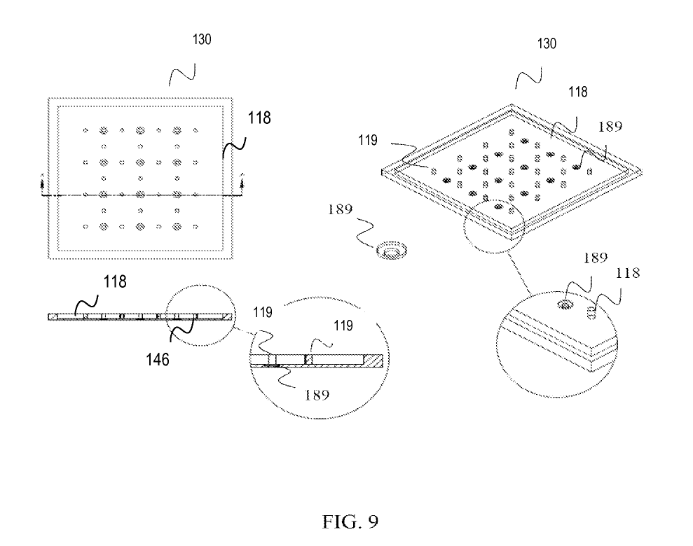

As shown in FIGS. 8 and 9 and discussed in further detail below, die 100 may include one or more cooling plugs 189. The one or more cooling plugs 189 may be constructed to provide a thermal interface directly with a bottom portion of reservoir 118. The one or more cooling plugs 189 may be formed of at least one thermally conductive material such as, for example, one or more metals. The one or more cooling plugs 189 may also include an external interface portion as described above to enable coupling to, for example, one or more heat dissipation structures external to die 100.

In some examples, TRV 116 may be constructed to provide a thermal path for the transfer of heat from functional die layers 121-123, and/or from coolant fluid disposed within channels or reservoir 118 of an intra-die cooling structure. For this purpose, TRV 116 may be constructed of a metal or other thermally conductive material.

In addition to or instead of thermal transfer and structural support, TRV 116 may be adapted to transfer electrical energy. In one embodiment, TRV 116 may be adapted to transfer electrical signal energy (e.g., electrical signals) between circuits internal to die 100 to electrical circuits disposed elsewhere, such as in a different IC die. In another embodiment, through-reservoir via 116 may be adapted to transfer electrical power energy (e.g., supply power) to and from circuits of die 100.

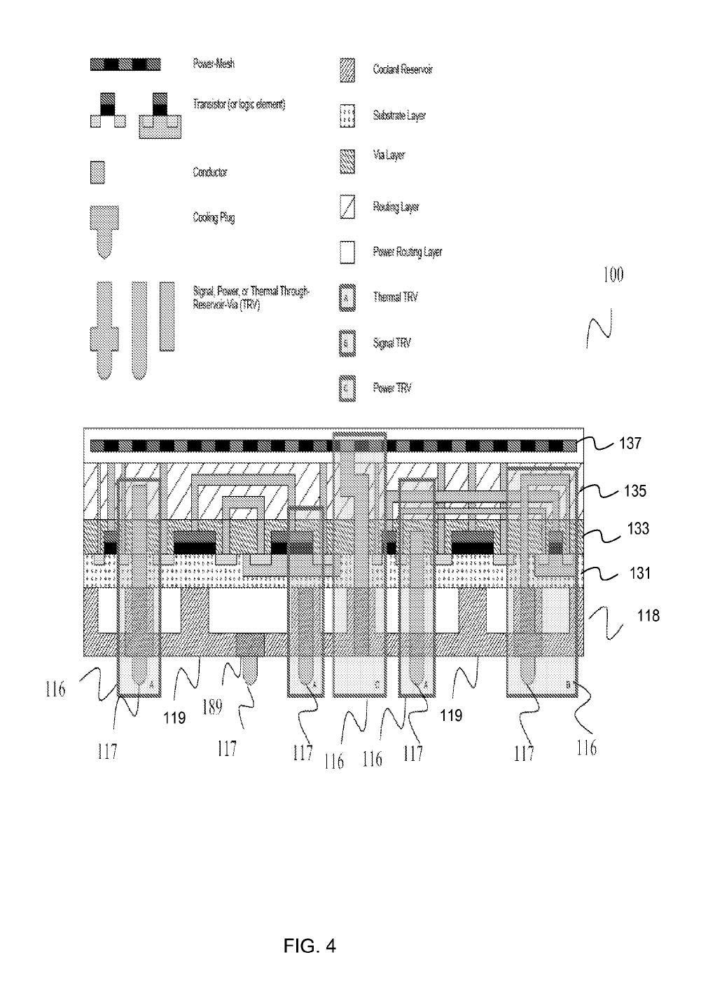

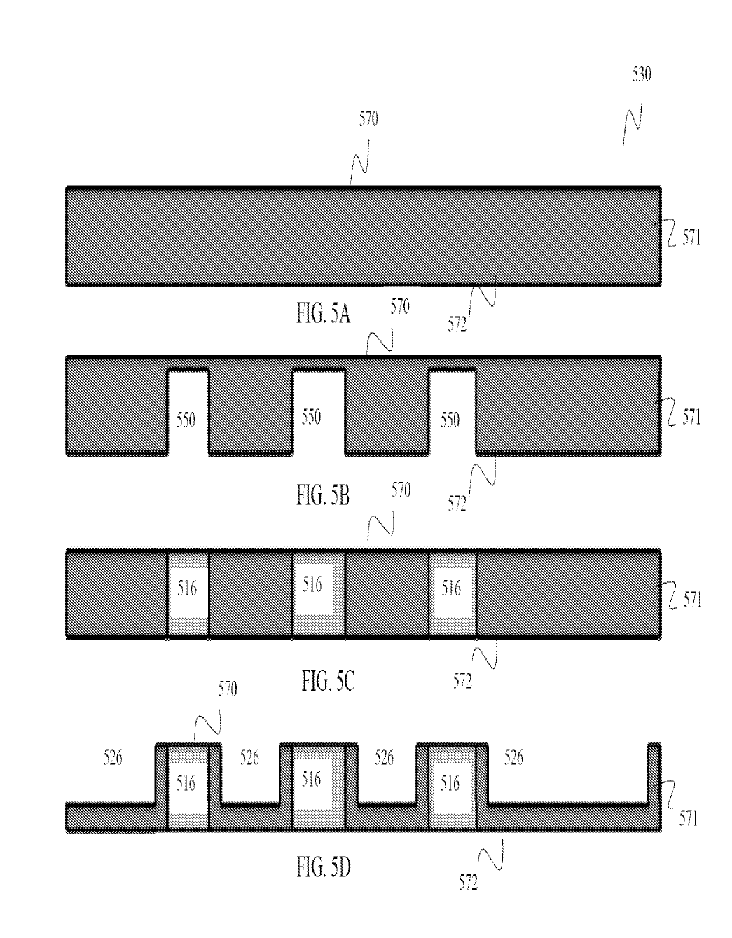

FIG. 4 illustrates generally a cross-sectional side view of a semiconductor die 100 that includes an intra-die cooling structure including various examples of TRV 116 according to various aspects of the invention described herein. As depicted, die 100 includes a coolant reservoir 118, a semiconductor substrate layer 131 (e.g., a device layer doped with impurities to form portions of semiconductor device structures, for example transistors), a via layer 133 providing electrical contacts to doping regions of the semiconductor substrate layer 131, a routing layer 135 for interconnection between semiconductor device structures, and/or a power routing layer 137 to enable coupling of semiconductor device structures to one or more power rails carrying supply power for die 100.

As depicted, die 100 includes a plurality of TRV 116. Die 100 may further include one or more reservoir pillars 119 constructed to provide structural support to reservoir 118. In the example of FIG. 4, TRVs 116 designated by reference A may be constructed and arranged to provide structural support to reservoir 118 and carry thermal energy from locations internal the die 100 externally. In a first embodiment shown at the left of FIG. 4, a TRV 116 is constructed to carry thermal energy from routing layer 135, through reservoir 118, and external to die 100 via an external interface portion 117. In a second embodiment shown at the middle of FIG. 4, a TRV 116 is constructed to carry thermal energy from reservoir 118 external to die 100. In a third embodiment shown at the right of FIG. 4, a TRV 116 is constructed to carry thermal energy from a metallization/via layer 137 external to die 100. As also shown in this embodiment, a TRV 116 may be constructed such that a conductive material of TRV 116 is at least partially exposed to coolant fluid housed in reservoir 118 to improve thermal transfer characteristics.

A TRV 116 via may be constructed to transfer thermal energy from semiconductor substrate layer 131, metallization/via layer 133, routing layer 135, power routing layer 137, or any other functional layer of die 100.

As designated by reference B in FIG. 4, die 100 may further include TRV 116 configured instead or in addition as a path to transfer electrical signal energy (e.g., electrical energy for the communication of data and or control signals) in addition to providing structural support for reservoir 118. At one end, the TRV 116 may be electrically coupled to at least one semiconductor device structure by a route and/or via through routing layer 135, metallization layer 133, and/or semiconductor substrate layer 131. In other embodiments, a TRV 116 may itself extend into metallization/via 133 or routing 135 layers for electrical interconnect with one or more circuits or transistors of die 100. An external interface portion 117 may enable electrical interconnection to an IC package or a printed circuit board (PC board). As such, other electrical devices, for example circuits of another semiconductor die, may be coupled to circuits internal to die 100.

As designated by reference C in FIG. 4, die 100 may also include one or more TRV 116 that also or instead are configured to transfer power energy (e.g., supply power for die 100 or other electrical circuitry external to die 100). TRV 116 designated by reference C depicted in FIG. 4 is arranged to provide a path for power to be coupled from power routing layer 137, through other integral layers of die 100, external to die 100.

In alternative embodiments as shown by the power through-reservoir via C, instead of external interface portions 117, TRV 116 may be constructed to provide an exposed electrical contact (e.g., solder pad) at an exterior surface of die 100. According to these embodiments, an electrical connection with a PC board or IC package may be made by an electrically conductive paste or cream or other known means.

In some examples, a TRV 116 configured to transfer electrical signal or power energy may include at least one insulating material at an outer surface of the TRV 116 to electrically isolate the TRV from the fluid housed in the coolant reservoir 118. In other examples, a TRV 116 configured to transfer thermal energy may not include an insulating layer between thermally conductive material (e.g., a metal) and fluid, to improve thermal transfer characteristics between the TRV 116 and the fluid.

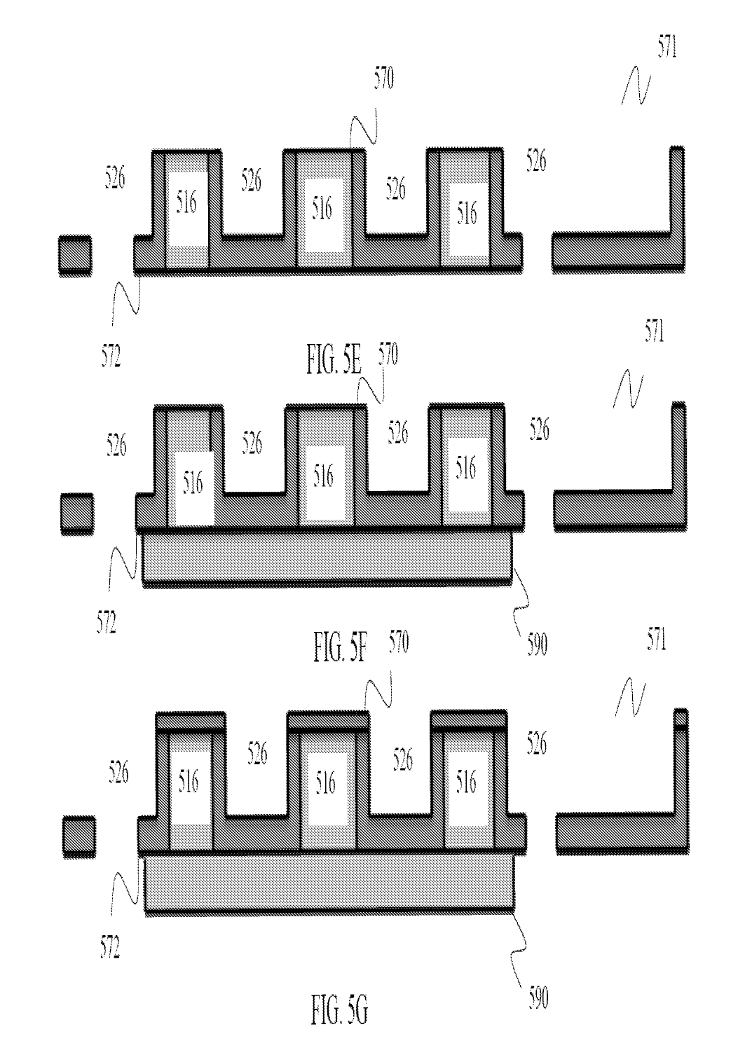

The embodiments of TRV 116 depicted in FIGS. 5A-5G show TRV 116 adapted to be dedicated to a particular function, for example, thermal, electrical, or power energy transfer, in addition to providing structural support for reservoir 118. In other embodiments not depicted, any one TRV 116 may be adapted to provide multiple functions. For example, a single TRV 116 may be adapted to provide a thermal conduit for the transfer of heat energy, and may also be adapted to provide a path for transfer of electrical signals or power. Energy transfer according to a multi-function through-reservoir via 116 may be accomplished by time division or otherwise multiplexing. For example, circuits of die 100 may be adapted to transmit or receive electrical signals using a particular via 116 at times when power transfer through that via 116 is unnecessary.

FIG. 5A-G illustrate generally a method of forming a cooling structure reservoir 511 that includes a plurality of through-reservoir vias (TRV) 516 according to one embodiment. At FIG. 5A, a substrate 571 is provided. In one embodiment, substrate 571 is formed of a semiconductor material such as silicon. In other embodiments, substrate 571 may be formed of any material sufficient to form a cavity adapted to house a fluid.

At FIG. 5B, a plurality of recesses 550 are formed in a second surface 572 of substrate 571. Recesses 550 may be formed using a subtractive or additive process. In one embodiment, the recesses 550 are evenly spaced apart. In another embodiment, recesses 550 are formed in both X and Y dimensions with respect to substrate 571. As such, a two dimensional array of TRV 516 may be formed. In an embodiment, one or more recesses 550 may be constructed and arranged such that one or more portions of TRV 516 formed in recesses 550 may interface with corresponding portions of TRV 516 formed in other integral layers of an IC die 100, for example, TRV 516 formed of a conductive material and configured to extend into the semiconductor substrate, metallization, routing, or other integral layers of die 100 for the transfer of thermal, electrical signal, or electrical power energy from the layers of die 100.

At FIG. 5C, recesses 550 are filled with a material to be formed into TRV 516. According to embodiments where a TRV 516 is adapted to transfer thermal energy, the material may be a thermally conductive material such as a thermally conductive metal. In some embodiments, the material may be an electrically conductive material, such as copper or aluminum. In some embodiments, TRV 516 may be formed of different materials for different purposes.

Also in FIG. 5C, a first surface 570 of substrate 571 may be etched, grinded, or otherwise reduced to provide a level surface and expose an upper portion of vias 516. First surface 570 may further be polished to provide a smooth and level surface for further processing or for electrical/thermal connection with other portions of TRV 516.

At FIG. 5D, material may be removed to a certain depth from first surface 570 at portions between vias 516 to form recesses 526 for coolant fluid to be disposed in a resulting reservoir. The embodiment shown in FIG. 5D depicts material removal between TRVs 516 to form recesses 526. In one embodiment, material removal forms recessed trenches in both X and Y orientations.

In some embodiments, where direct thermal contact with fluid disposed in reservoir is not desired, substrate 571 is etched such that a layer of substrate material remains surrounding TRV 516. Surrounding substrate material may provide electric, thermal, and/or chemical insulation, and may enable etch processes that are incompatible with TRV 516 material. In another embodiment, substrate material surrounding TRV 516 may be removed partially or entirely, exposing vias 516 to fluid once reservoir 511 is filled. In an embodiment, partially or entirely exposed TRV 516 may provide improved thermal transfer characteristics with respect to fluid disposed in the reservoir.

In an embodiment, at FIG. 5F, a heat slug 590 or other thermally conductive structure may be formed at second surface 572. In various embodiments, heat slug 590 may be formed of any thermally conductive material now known or later developed, such as one or more metals. In one embodiment, the heat slug 590 may be formed using a sputtering process. In one such embodiment, TI/Au layer stack is sputtered on surface 572 as a seed layer. In an embodiment, the heat slug 590 is formed by a copper electroplating process.

In alternative embodiments not depicted, TRV 516 may be formed by an additive process as opposed to the subtractive process described above. The one or more additive processes may be used to deposit materials and form TRV 516 on first surface 570 of substrate 571.

In one additive process embodiment, a functional powder embedded in a matrix material such as an ultraviolet sensitive polymer material is deposited on surface 570. According to this embodiment, a photolithographic process may be used to selectively harden or soften deposited powder at those areas where TRV 516 are to be formed. In an embodiment, once TRV 516 have been formed, a subtractive process, such as etching, is used to remove unwanted deposited material and/or to form a shape of TRV 516.

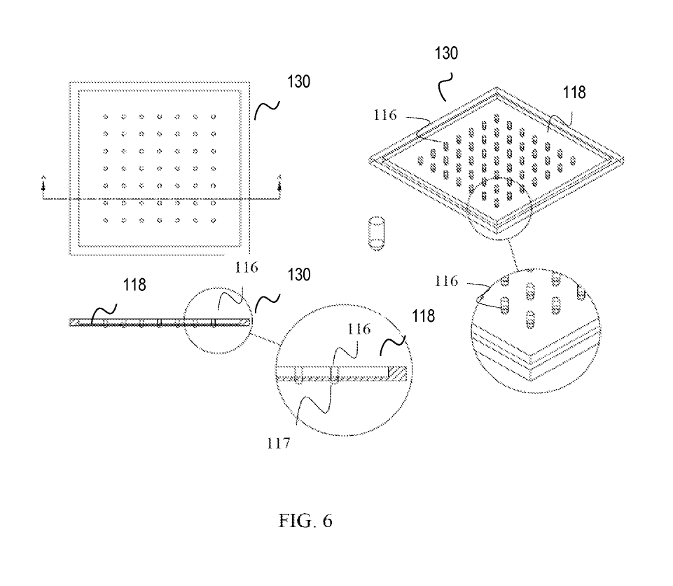

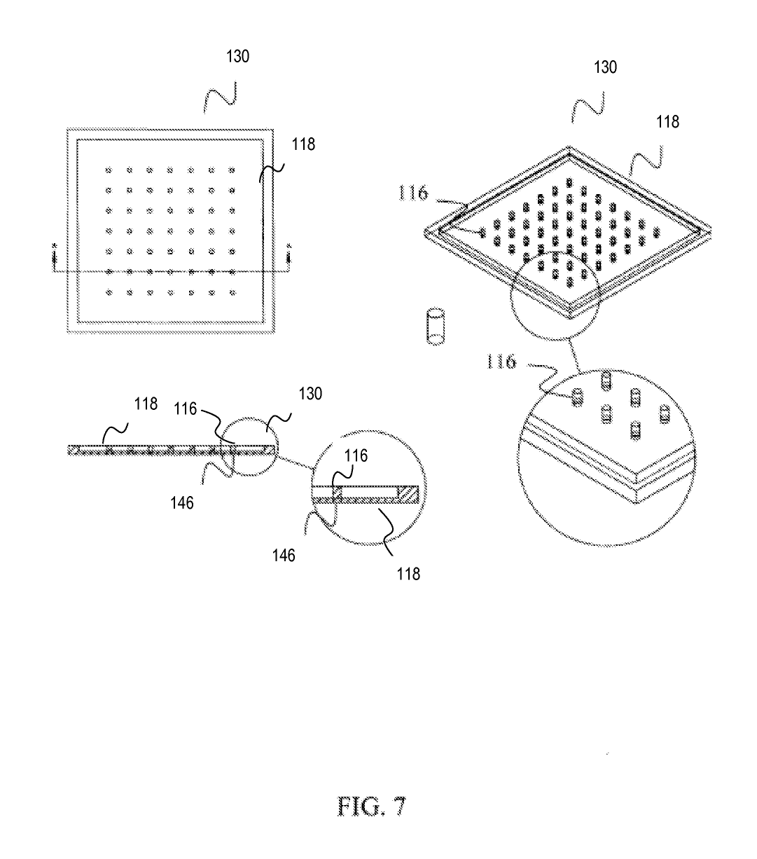

FIG. 6 illustrates generally a cooling structure reservoir 118 in an integral layer 130 of an IC die 100. As depicted, reservoir 118 includes a plurality of TRV 116 in a spaced arrangement. The TRV 116 may provide structural support for reservoir 118. In an embodiment, as depicted, at least some of the TRV 116 may include external interface portions 117 constructed to enable electrical or thermal contact with TRV 116 from external to die 100 for purposes of electrical or thermal energy transfer. FIG. 7 depicts an embodiment of a cooling structure reservoir 118 that includes a plurality of TRV 116 that include at least one contact 146 (e.g., solder pad) presented at an exterior surface of die 100 to enable electrical or thermal coupling to structures or devices external to die 100. In an embodiment, the contact 146 is constructed to be flush with the external surface of die 100.

FIG. 8 illustrates generally a cooling structure reservoir layer 130 of an IC die 100 that includes both support pillars 119 and cooling plugs 189 according to one embodiment. Reservoir 118 depicted in FIG. 8 does not include TRV 116 as described herein. Cooling plug 189 may be formed in or near an exposed surface of reservoir 118 to enable thermal coupling external to die 100 via external interface portions 117 of cooling plugs 189 as described above. The cooling plugs 189 may include a surface opposed to an external surface of die 100 and arranged to be in contact with fluid disposed in reservoir 118. Cooling plugs 189 may provide an interface with a fluid housed in reservoir to transfer thermal energy from the fluid external to die 100. The cooling plugs 189 may not provide structural support to reservoir 118 (plug 189 depicted in FIG. 8 is shown in front of a support pillar 119 or other structure). As also shown in FIG. 8, cooling plugs 189 may include an external interface portion 117 as described above. As shown in FIG. 9, cooling plug 189 may include an electrical contact 146 presented at an exterior surface of die 100 as described herein. In embodiments not depicted, a cooling structure reservoir layer 130 may include any combination of support pillars 119, TRV 116, and/or cooling plugs 189.

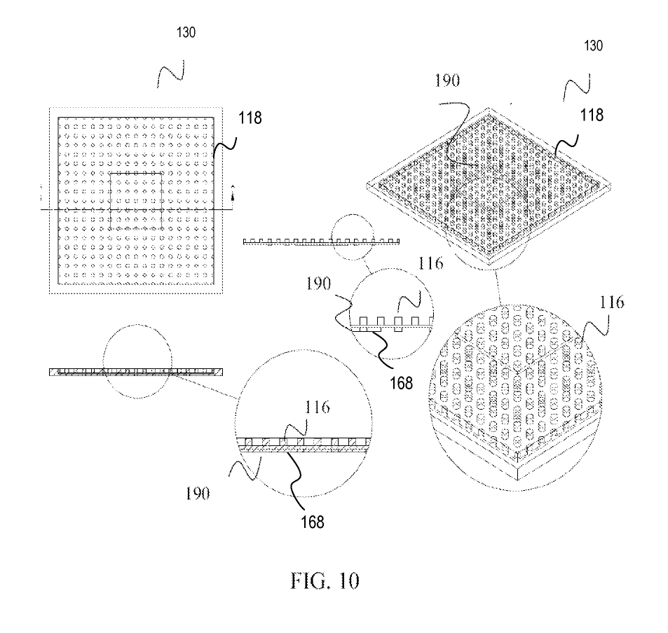

FIG. 10 illustrates generally a cooling structure reservoir layer 130 of an IC die 100 that includes a plurality of TRVs 116 and a thermal slug 190. Thermal slug 190 may present a larger surface area within reservoir 118 in contact with a fluid housed within reservoir 118. Thermal slug 190 may improve thermal transfer from fluid housed within reservoir 118 external to die 100. As shown, in an embodiment, at least some of a plurality of TRVs 116 may be coupled to thermal slug 190. In various embodiments, the thermal slug 190 may be coupleable to a heat sink or other thermal dissipation structure external to die 100 (not shown in FIG. 10). In an embodiment, thermal slug 190, TRV 116, and/or cooling plugs 189 may be formed in contact with one another. In other embodiments, these components may be formed of individual structures that are then thermally, electrically, or otherwise coupleable.

Various embodiments of the invention have been described. These and other embodiments are within the scope of the following claims.

1. An integrated circuit (IC) device comprising:
a plurality of integral layers;
at least one coolant reservoir integral to at least one of the plurality of integral layers and configured to house a fluid for the thermal management of the IC device; and
at least one through reservoir via (TRV) configured to provide structural support for the at least one coolant reservoir, wherein the at least one TRV is further configured to provide a path for the transfer of energy between the IC device and one or more additional structures external to the IC device.

2. The IC device of claim 1, wherein the at least one TRV is configured to provide a path for the transfer of thermal energy between the IC device and the one or more additional structures external to the IC device.

3. The IC device of claim 2, wherein the TRV is configured to provide a path for the transfer of thermal energy to the one or more additional structures external to the IC device from one or more of:
at least one of the plurality of integral layers of the IC device; and
the coolant reservoir.

4. The IC device of claim 1, wherein the at least one TRV comprises a thermally conductive material.

5. The IC device of claim 4, wherein the thermally conductive material includes at least one surface exposed to the fluid housed in the coolant reservoir.

6. The IC device of claim 1, wherein the at least one TRV is configured to provide a path for the transfer of electrical energy between the IC device and the one or more additional structures external to the IC device.

7. The IC device of claim 6, wherein the at least on TRV comprises at least one insulating material at an outer surface of the TRV to electrically isolate the TRV from the fluid housed in the coolant reservoir.

8. The IC device of claim 7, wherein the electrical energy is electrical signal energy.

9. The IC device of claim 7, wherein the electrical energy is electrical power energy.

10. The IC device of claim 1, wherein the one or more additional structures external to the IC device comprises one or more additional structures selected from the group consisting of:
an electrical circuit;
a heat sink;
an IC package; and
a printed circuit (PC) board.

11. The IC device of claim 1, wherein the at least one TRV further comprises:
at least one external interface portion presented at an external surface of the IC device.

12. The IC device of claim 11, wherein the at least one external interface portion is configured to be coupled with a corresponding interface portion of the one or more additional structures external to the IC device.

13. The IC device of claim 12, wherein the at least one external interface portion is configured to be coupled with a corresponding interface portion of the one or more additional structures external to the IC device that includes a bump of a flip-chip or ball grid array.

14. A method, comprising:
transferring energy between an IC device and at least one structure external to the IC device, wherein the IC device includes a plurality of integral layers and a coolant reservoir integral to at least one of the plurality of integral layers, wherein the coolant reservoir is configured to house a fluid for the thermal management of the IC device; and
wherein transferring the energy comprises transferring the energy through at least one through reservoir via (TRV) configured to provide structural support for the at least one coolant reservoir.

15. The method of claim 14, wherein transferring the energy through at least one through reservoir via (TRV) comprises transferring thermal energy between the IC device and the one or more additional structures external to the IC device.

16. The method of claim 15, wherein transferring the energy comprises transferring the energy from one or more of:
at least one of the plurality of integral layers of the IC device; and
the coolant reservoir.

17. The method of claim 14, wherein the at least one TRV comprises a thermally conductive material.

18. The method of claim 17, wherein the thermally conductive material includes at least one surface exposed to the fluid housed by the coolant reservoir.

19. The method of claim 14, wherein transferring the energy through at least one through reservoir via (TRV) comprises transferring electrical energy between the IC device and the one or more additional structures external to the IC device.

20. The method of claim 19, wherein the at least on TRV comprises at least one insulating material at an outer surface of the TRV to electrically isolate the TRV from the fluid housed in the coolant reservoir.

21. The method of claim 19, wherein transferring electrical energy between the IC device and the one or more additional structures external to the IC device comprises transferring electrical signal energy.

22. The method of claim 19, wherein transferring electrical energy between the IC device and the one or more additional structures external to the IC device comprises transferring electrical power energy.

23. The method of claim 14, wherein the one or more additional structures external to the IC device comprises one or more additional structures selected from the group consisting of:
an electrical circuit;
a heat sink;
an IC package; and
a printed circuit (PC) board.

24. An integrated circuit (IC) device, comprising:
a plurality of layers;
means for housing a fluid for the thermal management of the IC device integral to at least one of the plurality of integral layers; and
means for providing structural support for the means for housing the fluid, wherein the means for providing structural support are further for providing a path for the transfer of energy between the IC device and one or more additional structures external to the IC device.

25. The IC device of claim 24, wherein the transferred energy comprises thermal energy.

26. The IC device of claim 25, wherein the transferred energy is transferred from one or more of:
at least one of the plurality of integral layers of the IC device; and
the coolant reservoir.

27. The IC device of claim 24, wherein the means for providing structural support comprise a thermally conductive material.

28. The IC device of claim 27, wherein the means for providing structural support include at least one surface exposed to the fluid housed by the coolant reservoir.

29. The IC device of claim 24, wherein the transferred energy comprises electrical energy.

30. The IC device of claim 29, wherein the means for providing structural support comprises at least one insulating material at an outer surface to electrically isolate the TRV from the fluid housed in the coolant reservoir.

31. The IC device of claim 30, wherein the transferred energy comprises electrical signal energy.

32. The IC device of claim 30, wherein the transferred energy comprises energy electrical power energy.

33. The IC device of claim 24, wherein the one or more additional structures external to the IC device comprises one or more additional structures selected from the group consisting of:
an electrical circuit;
a heat sink;
an IC package; and
a printed circuit (PC) board.
